(19) United States
(12) Patent Application Publication
(10) Pub. No.: US 2013/0206591 A1
(43) Pub. Date: Aug. 15, 2013

(54) Sputtering Target for Magnetic Recording Film and Method for Producing Same

(71) Applicants: Hideo Takami, Ibaraki (JP); Atsushi Nara, Ibaraki (JP); Shin-ichi Ogino, Ibaraki (JP); Yuichiro Nakamura, Ibaraki (JP)

(72) Inventors: Hideo Takami, Ibaraki (JP); Atsushi Nara, Ibaraki (JP); Shin-ichi Ogino, Ibaraki (JP); Yuichiro Nakamura, Ibaraki (JP)

(73) Assignee: JX NIPPON MINING & METALS CORPORATION, Tokyo (JP)

(21) Appl. No.: 13/880,865

(22) PCT Filed: Nov. 9, 2011
(86) PCT No.: PCT/JP2011/075799

§ 371 Date: Apr. 22, 2013

(30) Foreign Application Priority Data
Dec. 17, 2010 (JP) 2010-281872

(51) Int. Cl. C23C 14/34

(52) U.S. Cl. CPC C23C 14/3414
USPC 204/298.13; 419/19

(57) ABSTRACT

Provided is a sputtering target for a magnetic recording film containing SiO₂, wherein the sputtering target for a magnetic recording film contains B (boron) in an amount of 10 to 1000 wtppm. An object of this invention is to obtain a sputtering target for a magnetic recording film capable of inhibiting the formation of cristobalites in the target which cause the generation of particles during sputtering, shortening the burn-in time, and realizing a stable discharge with a magnetron sputtering device.

### BACKGROUND

The present invention relates to a sputtering target for a magnetic recording film for use in the deposition of a magnetic thin film of a magnetic recording medium, and particularly of a magnetic recording layer of a hard disk adopting the perpendicular magnetic recording system, and to a sputtering target capable of inhibiting the formation of cristobalites that cause the generation of particles during sputtering, and shortening the time required from the start of sputtering to deposition, and the time is hereinafter referred to as the “burn-in time”.

In the field of magnetic recording as represented with hard disk drives, a material based on Co, Fe or Ni as ferromagnetic metals is used as the material of the magnetic thin film which is used for the recording. For example, Co—Cr-based or Co—Cr—Pt-based ferromagnetic alloys with Co as its main component are used for the recording layer of hard disks adopting the longitudinal magnetic recording system.

Moreover, composite materials of Co—Cr—Pt-based ferromagnetic alloys with Co as its main component and nonmagnetic inorganic matter are often used for the recording layer of hard disks adopting the perpendicular magnetic recording system which was recently put into practical application.

A magnetic thin film of a magnetic recording medium such as a hard disk is often produced by sputtering a ferromagnetic material sputtering target having the foregoing materials as its components in light of its high productivity. Moreover, SiO₂ is sometimes added to this kind of sputtering target for a magnetic recording film in order to magnetically separate the alloy phase.

As a method of manufacturing a ferromagnetic material sputtering target, the melting method or powder metallurgy may be considered. It is not necessarily appropriate to suggest which method is better since it will depend on the demanded characteristics, but a sputtering target made of ferromagnetic alloys and nonmagnetic inorganic particles used for the recording layer of hard disks adopting the perpendicular magnetic recording system is generally manufactured with powder metallurgy. This is because the inorganic particles of SiO₂ or the like need to be uniformly dispersed within the alloy substrate, which is difficult to achieve with the melting method.

For example, proposed is a method of performing mechanical alloying to an alloy powder having an alloy phase prepared by the rapid solidification method and a powder configuring the ceramic phase, causing the powder configuring the ceramic phase to be uniformly dispersed in the alloy powder, and performing hot press thereto in order to obtain a sputtering target for use in a magnetic recording medium (Patent Document 1).

The target structure in the foregoing case appears to be such that the base metal is bonded in a milt (cod fish sperm) shape and surrounded with SiO₂ (ceramic) (FIG. 2 of Patent Document 1) or dispersed in a thin string shape (FIG. 3 of Patent Document 1). While it is blurred in the other diagrams, the target structure in such other diagrams is also assumed to be of the same structure. It cannot be said that this kind of structure of a sputtering target is preferred for a magnetic recording medium, for it entails the problems described later. Note that the spherical substance shown in FIG. 4 of Patent Document 1 is mechanical alloying powder, and is not a structure of the target.

Moreover, without having to use the alloy powder prepared by the rapid solidification method, it is also possible to produce a ferromagnetic material sputtering target: namely, by preparing commercially available raw material powders for the respective components configuring the target, weighing these raw material powders to achieve the intended composition, mixing the raw material powders with a known method such as a ball mill, and molding and sintering the mixed powder via hot press.

There are various types of sputtering devices, but a magnetron sputtering device comprising a DC power source is broadly used for its high productivity for the deposition of the foregoing magnetic recording film. This sputtering method causes a positive electrode substrate and a negative electrode target to face each other, and generates an electric field by applying high voltage between the substrate and the target under an inert gas atmosphere.

Here, the sputtering method employs a fundamental principle where inert gas is ionized, plasma composed of electrons and positive ions is formed, and the positive ions in the plasma collide with the target (negative electrode) surface so as to sputter the atoms configuring the target. The discharged atoms adhere to the opposing substrate surface, wherein the film is formed. As a result of performing the sequential process described above, the material configuring the target is deposited on the substrate.

As described above, the sputtering target for a magnetic recording film is sometimes doped with SiO₂ in order to magnetically separate the alloy phase. Nevertheless, when SiO₂ is added to the magnetic metal material, there is a problem in that micro cracks are generated in the target and the generation of particles during sputtering increases.

There is an additional drawback with a SiO₂-doped magnetic material target, in that the burn-in time becomes longer compared to a magnetic material target that is not doped with SiO₂.

While there was some debate as to whether this was due to problems related to the SiO₂ itself, because the SiO₂ had transformed, or problems related to the interaction with other magnetic metals or additive materials, the fundamental cause had not been determined. In most cases, the problems were considered inevitable and were quietly condoned or overlooked. However, it is necessary to maintain the characteristics of magnetic films at a high level to meet current demands, and the further improvement of sputtered film characterizes is being demanded.

With conventional technologies, certain documents describe the technique of adding SiO₂ to a sputtering target using a magnetic material. Patent Document 2 discloses a target including a metal phase as a matrix phase, a ceramic phase that is dispersed in the matrix phase, and an interfacial reaction phase of the metal phase and the ceramic phase, wherein the relative density is 99% or more. While SiO₂ is included as an option as the ceramic phase, Patent Document 2 has no recognition of the foregoing problems and fails to propose any solution to such problems.

Upon producing a CoCrPt—SiO₂ sputtering target, Patent Document 3 proposes calcining Pt powder and SiO₂ powder, mixing Cr powder and Co powder to the obtained calcined powder, and performing pressure sintering thereof. Nevertheless, Patent Document 3 has no recognition of the foregoing problems and fails to propose any solution to such problems.

Patent Document 4 discloses a sputtering target including a metal phase containing Co, a ceramic phase having a grain size of 10 μm or less, and an interfacial reaction phase of the metal phase and the ceramic phase, wherein the ceramic phase is scattered in the metal phase. It proposes that SiO₂ is included as an option as the ceramic phase. Nevertheless, Patent Document 4 has no recognition of the foregoing problems and fails to propose any solution to such problems.

Patent Document 5 proposes a sputtering target containing non-magnetic oxide in an amount of 0.5 to 15 mol %, Cr in an amount of 4 to 20 mol %, Pt in an amount of 5 to 25 mol %, B in an amount of 0.5 to 8 mol %, and remainder being Co. While SiO₂ is included as an option as the non-magnetic oxide, Patent Document 5 has no recognition of the foregoing problems and fails to propose any solution to them.

Note that Patent Document 6 is also listed as a reference, but this document discloses technology of producing cristobalite particles as filler of sealants for semiconductor elements such as memories. Patent Document 6 is technology that is unrelated to a sputtering target, but it relates to SiO₂ cristobalites.

Patent Document 7 relates to a carrier core material for use as a electrophotographic developer. While Patent Document 7 is technology that is unrelated to a sputtering target, it relates to the types of crystals related to SiO₂. One type is SiO₂ quartz crystals, and the other type is cristobalite crystals.

While Patent Document 8 is technology that is unrelated to a sputtering target, it explains that cristobalite is a material that impairs the oxidation protection function of silicon carbide.

Patent Document 9 describes a sputtering target for forming an optical recording medium protection film having a structure where patternless SiO₂ is dispersed in the zinc chalcogenide base metal. Here, the transverse rupture strength of the target made of zinc chalcogenide-SiO₂ and the generation of cracks during sputtering are affected by the form and shape of SiO₂. It also discloses that when the SiO₂ is patternless (amorphous), the target will not crack during sputtering even with high-power sputtering.

While this is a suggestion in some ways, Patent Document 9 first and foremost relates to a sputtering target for forming an optical recording medium protection film using zinc chalcogenide, and it is totally unknown as to whether it can resolve the problems of a magnetic material having a different matrix material.

Patent Document 10 proposes a sputtering target containing non-magnetic oxide in an amount of 0.5 to 15 mol %, Cr in an amount of 4 to 20 mol %, Pt in an amount of 5 to 25 mol %, B in an amount of 0.5 to 8 mol %, and remainder being Co. While SiO₂ is included as an option as the non-magnetic oxide, Patent Document 10 has no recognition of the foregoing problems and fails to propose any solution to such problems.

[Patent Document 1] Japanese Patent Laid-open Publication No. H10-88333

[Patent Document 2] Japanese Patent Laid-open Publication No. 2006-45587

[Patent Document 3] Japanese Patent Laid-open Publication No. 2006-176808

[Patent Document 4] Japanese Patent Laid-open Publication No. 2008-179900

[Patent Document 5] Japanese Patent Laid-open Publication No. 2009-1861

[Patent Document 6] Japanese Patent Laid-open Publication No. 2008-162849

[Patent Document 7] Japanese Patent Laid-open Publication No. 2009-80348

[Patent Document 8] Japanese Patent Laid-open Publication No. H10-158097

[Patent Document 9] Japanese Patent Laid-open Publication No. 2000-178726

[Patent Document 10] Japanese Patent Laid-open Publication No. 2009-132976

### SUMMARY OF THE INVENTION

### Technical Problem

A compound material made of ferromagnetic alloy and non-magnetic inorganic substance is often used in a sputtering target for a magnetic recording film, and SiO₂ is sometimes added as the inorganic substance. Nevertheless, with a target to which SiO₂ is added, there is a problem in that numerous particles are generated in the sputtering process, and a longer burn-in time is required. As the SiO₂ raw material to be added, a formless (amorphous) raw material is used, and, while the target will not crack during high-power sputtering, there is a problem in that cristobalites are easily formed in the sintering process, and this consequently leads to the generation of particles.

### Solution to Problem

In order to solve the foregoing problem, as a result of intense study, the present inventors devised a method of adding B (boron) in an amount of 10 wtppm or more in addition to adding SiO₂ to the sputtering target for a magnetic recording film. In other words, the present inventors discovered that, as a result of inhibiting the formation of cristobalites that cause the generation of particles during sputtering, it is possible to inhibit micro cracks of the target and the generation of particles during sputtering, and also shorten the burn-in time. B, hereinafter, is referred to as boron.

Based on the foregoing discovery, the present invention provides:

1) A sputtering target for a magnetic recording film containing SiO₂, wherein the sputtering target for a magnetic recording film contains B (boron) in an amount of 10 to 1000 wtppm;

2) The sputtering target for a magnetic recording film according to 1) above, wherein the sputtering target for a magnetic recording film is made from Cr in an amount of 20 mol % or less, SiO₂ in an amount of 1 mol % or more and 20 mol % or less, and remainder being Co;

3) The sputtering target for a magnetic recording film according to 1) above, wherein the sputtering target for a magnetic recording film is made from Cr in an amount of 20 mol % or less, Pt in an amount of 1 mol % or more and 30 mol % or less, SiO₂ in an amount of 1 mol % or more and 20 mol % or less, and remainder being Co; and

4) The sputtering target for a magnetic recording film according to 1) above, wherein the sputtering target for a magnetic recording film is made from Fe in an amount of 50 mol % or less, Pt in an amount of 50 mol % or less, and remainder being SiO₂.

The present invention additionally provides:

5) The sputtering target for a magnetic recording film according to any one of 1) to 4) above, additionally containing one or more elements selected from Ti, V, Mn, Zr, Nb, Ru, Mo, Ta, and W in an amount of 0.5 mol % or more and 10 mol % or less; and

6) The sputtering target for a magnetic recording film according to any one of 1) to 5) above, additionally containing, as an additive material, one or more components selected from carbon, oxide other than SiO₂, nitride and carbide.

7) The present invention additionally provides a sputtering target for a magnetic recording film according to any one of 1) to 6) above, wherein the sputtering target for a magnetic recording film has a relative density is 97% or higher.

The present invention additionally provides:

8) A method of producing the sputtering target for a magnetic recording film according to any one of 1) to 7) above, wherein Co and B are melted to prepare an ingot, the ingot is pulverized to have a maximum particle size of 20 μm or less, powder obtained thereby is mixed with a magnetic metal powder raw material, and mixed powder obtained thereby is sintered at a temperature of 1200° C. or less;

9) A method of producing the sputtering target for a magnetic recording film according to any one of 1) to 7) above, wherein SiO₂ powder is added to an aqueous solution with B₂O₃ dissolved therein, B₂O₃ is precipitated on a surface of the SiO₂ powder, powder obtained thereby is mixed with a magnetic metal powder raw material, and mixed powder obtained thereby is sintered at a temperature of 1200° C. or less; and

10) A method of producing the sputtering target for a magnetic recording film according to any one of 1) to 7) above, wherein SiO₂ powder is added to an aqueous solution with B₂O₃ dissolved therein, B₂O₃ is precipitated on a surface of the SiO₂ powder and calcined at 200° C. to 400° C., powder obtained thereby is mixed with a magnetic metal powder raw material, and mixed powder obtained thereby is sintered at a temperature of 1200° C. or less.

The sputtering target for a magnetic recording film target of the present invention adjusted as described above yields superior effects of being able to inhibit the generation of micro cracks in a target, inhibit the generation of particles during sputtering, and shorten the burn-in time. Since few particles are generated, a significant effect is yielded in that the percent defective of the magnetic recording film is reduced and cost reduction can be realized. Moreover, shortening of the burn-in time contributes significantly to the improvement of production efficiency.

### DETAILED DESCRIPTION OF THE INVENTION

The sputtering target for a magnetic recording film of the present invention is a sputtering target for a magnetic recording film made from a ferromagnetic alloy containing SiO₂, wherein the sputtering target for a magnetic recording film contains B in an amount of 10 to 1000 wtppm. In other words, the present invention is a sputtering target for a magnetic recording film in which crystallized SiO₂, which is cristobalite, is eliminated or reduced as much as possible.

A compound material made of ferromagnetic alloy and non-magnetic inorganic substance is often used in a sputtering target for a magnetic recording film, and SiO₂ is sometimes added as the inorganic substance.

However, a volume change associated with phase transition occurs, when the SiO₂ crystallizes and exists as cristobalites in the target. The volume change occurs during the temperature rise or temperature drop process of the target, of which temperature is roughly 270° C., and causes the generation of micro cracks in the target.

Since the foregoing micro cracks consequently cause the generation of particles during sputtering, it would be effective for the SiO₂ to exist as amorphous SiO₂ in the target than becoming crystallized and existing as cristobalites.

In order to prevent amorphous SiO₂ from becoming cristobalite, considered may be lowering the sintering temperature. However, a problem arises in that the target density will consequently decrease when the sintering temperature is lowered. Thus, as a method of sintering which yields a sufficiently high density even at a low temperature in which the formation of cristobalites will not occur, the present inventors discovered that the softening point of SiO₂ can be lowered by solidifying B in SiO₂.

As the amount of B to be contained, 10 to 1000 wtppm is desirable. This is because if the amount is less than 10 wtppm, the softening point of SiO₂ cannot be sufficiently lowered. Meanwhile, if the amount exceeds 1000 wtppm, the oxide tends to grow larger, and this will contrarily increase the generation of particles. A more desirable content of B is 10 to 300 wtppm.

As described above, while there is no particular limitation in the magnetic material as the sputtering target for a magnetic recording film, preferably used is a sputtering target for a magnetic recording film containing Cr in an amount of 20 mol % or less, SiO₂ in an amount of 1 mol % or more and 20 mol % or less, and remainder being Co, or a sputtering target for a magnetic recording film containing Cr in an amount of 20 mol % or less, Pt in an amount of 1 mol % or more and 30 mol % or less, SiO₂ in an amount of 1 mol % or more and 20 mol % or less, and remainder being Co, or a sputtering target for a magnetic recording film containing Fe in an amount of 50 mol % or less, Pt in an amount of 50 mol % or less, and remainder being SiO₂.

These are components required as the magnetic recording medium, and the blending ratio may be variously changed within the foregoing range. In the range, they are able to maintain characteristics as an effective magnetic recording medium.

In the foregoing cases also, the SiO₂ needs to exist as amorphous SiO₂ in the target without becoming crystallized and existing as cristobalites.

Note that when Cr described above is to be added as an essential component, the amount excludes 0 mol %. In other words, the amount of Cr to be included needs to be at least an analyzable lower limit or higher. If the Cr amount is 20 mol % or less, an effect can be yielded even in cases where trace amounts are added. The present invention covers all of the foregoing aspects. These elements are components that are required as a magnetic recording medium, and while the blending ratio may vary within the foregoing range, all of these components are able to maintain the characteristics as an effective magnetic recording medium.

In addition, also effective is the foregoing sputtering target for a magnetic recording film containing, as an additive element, one or more elements selected from Ti, V, Mn, Zr, Nb, Ru, Mo, Ta, and W in an amount of 0.5 mol % or more and 10 mol % or less. The additive element is an element that is added as needed in order to improve the characteristics as a magnetic recording medium.

Furthermore, also effective is the foregoing sputtering target for a magnetic recording film containing, as an additive element, an inorganic material of one or more components selected from carbon, oxide other than SiO₂, nitride and carbide.

Upon producing this kind of sputtering target for a magnetic recording film, the existence of B near SiO₂ during sintering is effective. As a method of adding B, a method of using Co—B powder as the raw material powder, or a method of using SiO₂ powder with B precipitated thereon is effective.

The raw material powder and a magnetic metal powder raw material are mixed, and sintering the product at a sintering temperature of 1200° C. or less. This low sintering temperature is effective for inhibiting the crystallization of the SiO₂. Moreover, as a result of using high-purity SiO₂, it is further possible to inhibit crystallization. In this respect, it is desirable to use high purity SiO₂ having a purity level of 4N or more, preferably 5N or more.

While the production method is now explained in detail, this production method is merely a representative and preferred example. In other words, the present invention is not limited to the following production method, and it should be easy to understanding that other production methods may also be adopted so as long as they are able to achieve the object and conditions of the present invention.

The ferromagnetic material sputtering target of the present invention can be manufactured with powder metallurgy. Foremost, B-doped raw material powder is prepared. As methods of obtaining the B-doped raw material powder, there are, for example, 1) a method of preparing an ingot by melting Co and B, and pulverizing the obtained ingot to obtain a Co—B powder, or 2) a method of placing SiO₂ powder in a B₂O₃ aqueous solution, drying the product, and thereby obtaining powder in which B₂O₃ is precipitated on the surface of the SiO₂ powder. In the method of 2) above, the SiO₂ powder with B₂O₃ precipitated thereon may be additionally calcined at 200 to 400° C. for 5 hours. It is thereby possible to promote the solidification of B₂O₃ and SiO₂.

Subsequently, powders of the respective metal elements and the SiO₂ powder raw material, and the powder raw material of the respective metal elements and the powder raw material of the additive metal elements are prepared as needed. Desirably, the maximum particle size of these powders is 20 μm or less.

Moreover, the alloy powders of these metals may also be prepared in substitute for the powders of the respective metal elements, and, desirably, the maximum particle size is also 20 μm or less in the foregoing case.

Meanwhile, if the particle size is too small, there is a problem in that oxidation is promoted and the component composition will not fall within the intended range. Thus, desirably, the particle size is 0.1 μm or more.

Subsequently, these raw material powders are weighed to obtain the intended composition, mixed and pulverized with well-known methods by using a ball mill or the like. If inorganic powder is to be added, it should be added to the metal powders at this stage.

Carbon powder, oxide powder other than SiO₂, nitride powder or carbide powder is prepared as the inorganic powder, and desirably, the maximum particle size of the inorganic powder is 5 μm or less. Meanwhile, if the particle size is too small, the powders become clumped together, and the particle size is therefore desirably 0.1 μm or more.

Moreover, as the mixer, a planetary screw mixer or a planetary screw agitator/mixer is preferably used. In addition, mixing is preferably performed in an inert gas atmosphere or a vacuum in consideration of the problem of oxidation in the mixing process.

By molding and sintering the obtained powder using a vacuum hot press device, and cutting it into an intended shape, it is possible to produce the ferromagnetic material sputtering target of the present invention. Here, sintering is performed at a sintering temperature of 1200° C. or less as described above.

This low sintering temperature is a temperature that is required for inhibiting the crystallization of SiO₂.

Moreover, the molding and sintering processes are not limited to the hot press method. A plasma discharge sintering method or a hot isostatic sintering method may also be used. The holding temperature in the sintering process is preferably set to the lowest within the temperature range in which the target can be sufficiently densified. Although this will depend on the composition of the target, in many cases a temperature range of 900 to 1200° C. is preferable.

### EXAMPLES

The present invention is now explained in detail with reference to the Examples and Comparative Examples. Note that these Examples are merely illustrative and the present invention shall in no way be limited thereby. In other words, various modifications and other embodiments are covered by the present invention, and the present invention is limited only by the scope of its claims.

### Examples 1, 2, Comparative Example 1

In Examples 1, 2, Co—B powder having an average grain size of 5 μm, Cr powder having an average grain size of 5 μm, and amorphous SiO₂ powder having an average grain size of 1 μm were prepared. The Co—B powder, Cr powder, and SiO₂ powder were weighed to achieve a target composition of 83 Co-12 Cr-5 SiO₂ (mol %). And, the B content was set to 100 wtppm in Example 1, 300 wtppm in Example 2, and 0 wtppm in Comparative Example 1.

Subsequently, the Co—B powder, Cr powder and SiO₂ powder were placed in a 10-liter ball mill pot together with zirconia balls as the grinding medium, and rotated and mixed for 20 hours.

This mixed powder was filled in a carbon mold and hot pressed under the following conditions; a vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

TABLE 1

| | | | | | Hot | Density | Num- |
|---|---|---|---|---|---|---|---|
| | | | | | Press | after | ber |
| | | Addi- | Cal- | B | Temper- | Hot | of |
| | | tion | cina- | content | ature | Press | Par- |
| | Composition Ratio (mol %) | of B | tion | (wtppm) | (° C.) | (%) | ticle |
| Example 1 | 83Co—12Cr—5SiO₂ | Co—B | No | 100 | 1040 | 97.81 | 3 |
| Example 2 | 83Co—12Cr—5SiO₃ | Co—B | No | 300 | 1040 | 98.68 | 5 |
| Compar- | 83Co—12Cr—5SiO₃ | none | No | 0 | 1040 | 96.20 | 25 |
| ative | | | | | | | |
| Example 1 | | | | | | | |
| Example 3 | 83Co—12Cr—5SiO₂ | B₂O₃ | No | 21 | 1040 | 97.51 | 4 |
| Example 4 | 83Co—12Cr—5SiO₃ | B₂O₃ | No | 70 | 1040 | 98.02 | 3 |
| Example 5 | 83Co—12Cr—5SiO₃ | B₂O₃ | No | 610 | 930 | 97.53 | 4 |
| Compar- | 83Co—12Cr—5SiO₃ | B₂O₃ | No | 7 | 1040 | 96.22 | 22 |
| ative | | | | | | | |
| Example 2 | | | | | | | |
| Example 6 | 83Co—12Cr—5SiO₂ | B₂O₃ | Done | 70 | 1040 | 98.58 | 2 |
| Example 7 | 78Co—12Cr—5Pt—5SiO₂ | B₂O₃ | Done | 70 | 1040 | 98.51 | 2 |
| Compar- | 78Co—12Cr—5Pt—5SiO₂ | none | No | 0 | 1040 | 96.34 | 23 |
| ative | | | | | | | |
| Example 3 | | | | | | | |
| Example 8 | 45Fe—45Pt—10SiO₂ | B₂O₃ | Done | 70 | 1100 | 97.89 | 3 |
| Compar- | 45Fe—45Pt—10SiO₂ | none | No | 0 | 1100 | 95.12 | 31 |
| ative | | | | | | | |
| Example 4 | | | | | | | |
| Example 9 | 78Co—12Pt—10SiO₂ | B₂O₃ | Done | 70 | 1040 | 97.67 | 3 |
| Compar- | 78Co—12Pt—10SiO₂ | none | No | 0 | 1040 | 95.21 | 32 |
| ative | | | | | | | |
| Example 5 | | | | | | | |
| Example 10 | 38Fe—38Pt—9SiO₂—15C | B₂O₃ | Done | 300 | 1100 | 97.51 | 30 |
| Compar- | 38Fe—38Pt—9SiO₂—15C | none | No | 0 | 1100 | 94.30 | 150 |
| ative | | | | | | | |
| Example 6 | | | | | | | |
| Example 11 | 68Co—10Cr—12Pt—2TiO₂—4SiO₂—4Cr₂O₃ | B₂O₃ | Done | 300 | 950 | 97.65 | 2 |
| Compar- | 68Co—10Cr—12Pt—2TiO₂—4SiO₂—4Cr₂O₃ | none | No | 0 | 950 | 96.47 | 13 |
| ative | | | | | | | |
| Example 7 | | | | | | | |
| Example 12 | 65Co—10Cr—15Pt—5SiO₂—5Ta₂O₅ | B₂O₃ | Done | 300 | 1000 | 97.85 | 3 |
| Compar- | 65Co—10Cr—15Pt—5SiO₂—5Ta₂O₅ | none | No | 0 | 1000 | 96.56 | 21 |
| ative | | | | | | | |
| Example 8 | | | | | | | |
| Example 13 | 71Co—8Cr—12Pt—3TiO₂—3SiO₂—3CoO | B₂O₃ | Done | 300 | 900 | 97.34 | 3 |
| Compar- | 71Co—8Cr—12Pt—3TiO₂—3SiO₂—3CoO | none | No | 0 | 900 | 95.56 | 25 |
| ative | | | | | | | |
| Example 9 | | | | | | | |
| Example 14 | 66Co—12Cr—14Pt—3Ru—5SiO₂ | B₂O₃ | Done | 300 | 1040 | 98.40 | 2 |
| Compar- | 66Co—12Cr—14Pt—3Ru—5SiO₂ | none | No | 0 | 1040 | 96.25 | 24 |
| ative | | | | | | | |
| Example 10 | | | | | | | |
| Example 15 | 66Co—10Cr—12Pt—1Ti—1V—1Mn—1Zr—1Nb—1Mo—1W—5SiO₂ | B₂O₃ | Done | 300 | 1000 | 97.46 | 8 |
| Compar- | 66Co—10Cr—12Pt—1Ti—1V—1Mn—1Zr—1Nb—1Mo—1W—5SiO₂ | none | No | 0 | 1000 | 95.86 | 25 |
| ative | | | | | | | |
| Example 11 | | | | | | | |
| Example 16 | 71Co—10Cr—12Pt—1SiN—1SiC—5SiO₂ | B₂O₃ | Done | 300 | 1040 | 97.57 | 2 |
| Compar- | 71Co—10Cr—12Pt—1SiN—1SiC—5SiO₂ | none | No | 0 | 1040 | 96.24 | 19 |
| ative | | | | | | | |
| Example 12 | | | | | | | |
| Example 17 | 66Co—12Cr—14Pt—3Ta—5SiO₂ | B₂O₃ | Done | 300 | 1040 | 98.15 | 2 |
| Compar- | 66Co—12Cr—14Pt—3Ta—5SiO₂ | none | No | 0 | 1040 | 96.33 | 23 |
| ative | | | | | | | |
| Example 13 | | | | | | | |

In Comparative Example 1, Co powder having an average grain size of 3 μm, Cr powder having an average grain size of 5 μm, and amorphous SiO₂ powder having an average grain size of 1 μm were prepared. The Co powder, Cr powder, and SiO₂ powder were weighed to achieve a target composition of 83 Co-12 Cr-5 SiO₂ (mol %). Here, B was not added.

Subsequently, the Co powder, Cr powder and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.81% in Example 1 and 98.68% in Example 2, and a higher density target was obtained compared to the relative density of 96.20% in Comparative Example 1. As a result of sputtering this target, the number of particles generated in a stationary state was 3 in Example 1 and 5 in Example 2, and it was confirmed that the number of particles decreased compared to the 25 particles of Comparative Example 1. Thus, when B is added in an amount of 10 wtppm or more, a high density target was obtained and the number of generated particles decreased.

### Examples 3 to 5, Comparative Example 2

In Examples 3 to 5, Co powder having an average grain size of 3 μm, Cr powder having an average grain size of 5 μm, and amorphous SiO₂ powder with B₂O₃ precipitated on the surface thereof and having an average grain size of 1 μm were prepared. The Co powder, Cr powder, and SiO₂ powder were weighed to achieve a target composition of 83 Co-12 Cr-5 SiO₂ (mol %). And the B content was set to 21 wtppm in Example 3, 70 wtppm in Example 4, and 610 wtppm in Example 5.

Subsequently, the Co powder, Cr powder and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 2, Co powder having an average grain size of 3 μm, Cr powder having an average grain size of 5 μm, and amorphous SiO₂ powder with B₂O₃ precipitated on the surface thereof and having an average grain size of 1 μm were prepared. The Co powder, Cr powder, and SiO₂ powder were weighed to achieve a target composition of 83 Co-12 Cr-5 SiO₂ (mol %). And the B content was 7 wtppm.

Subsequently, the Co powder, Cr powder and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C. (only in Example 5 , the temperature was set to 930° C.), retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.51% in Example 3, 98.02% in Example 4, and 97.53% in Example 5, and a higher density target was obtained compared to the relative density of 96.22% in Comparative Example 2. As a result of sputtering this target, the number of particles generated in a stationary state was 4 in Example 3, 3 in Example 4, and 4 in Example 5, and it was confirmed that the number of particles decreased compared to the 22 particles of Comparative Example 2. Thus, when B is added in an amount of 10 wtppm or more, a high density target was obtained and the number of generated particles decreased.

### Example 6

In Example 6, Co powder having an average grain size of 3 μm, Cr powder having an average grain size of 5 μm, and amorphous SiO₂ powder with B₂O₃ precipitated on the surface thereof and having an average grain size of 1 μm were prepared, and the SiO₂ powder was calcined at 300° C. for 5 hours.

The Co powder, Cr powder, and SiO₂ powder were weighed to achieve a target composition of 83 Co-12 Cr-5 SiO₂ (mol %). And the B content was 70 wtppm.

Subsequently, the Co powder, Cr powder and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

The relative density after hot press was 98.58%. As a result of sputtering this target, the number of particles generated in a stationary state was 2. Thus, when SiO₂ powder with B₂O₃ precipitated on the surface thereof is calcined, the solidification of B₂O₃ and SiO₂ is promoted, a high density target is obtained and the number of particles that were generated during sputtering decreases.

### Example 7, Comparative Example 3

In Example 7, Co powder having an average grain size of 3 μm, Cr powder having an average grain size of 5 μm, Pt powder having an average grain size of 2 μm, and amorphous SiO₂ powder with B₂O₃ precipitated on the surface thereof and having an average grain size of 1 μm were prepared. The Co powder, Cr powder, Pt powder and SiO₂ powder were weighed to achieve a target composition of 78 Co-12 Cr-5 Pt-5 SiO₂ (mol %). And, the B content was 70 wtppm.

Subsequently, the Co powder, Cr powder, Pt powder and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 3, Co powder having an average grain size of 3 μm, Cr powder having an average grain size of 5 μm, Pt powder having average grain size of 2 μm, and amorphous SiO₂ powder having an average grain size of 1 μm were prepared. The Co powder, Cr powder, Pt powder and SiO2 powder were weighed to achieve a target composition of 78 Co-12 Cr-5 Pt-5 SiO₂ (mol %). Here, B was not added.

Subsequently, the Co powder, Cr powder, Pt powder and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 98.51% in Example 7, and a higher density target was obtained compared to the relative density of 96.34% in Comparative Example 3. As a result of sputtering this target, the number of particles generated in a stationary state was 2 in Example 7, and it was confirmed that the number of particles decreased compared to the 23 particles of Comparative Example 3. Thus, when B is added in an amount of 10 wtppm or more, a high density target was obtained and the number of generated particles decreased.

### Example 8, Comparative Example 4

In Example 8, Fe powder having an average grain size of 7 μm, Pt powder having an average grain size of 2 μm, and amorphous SiO₂ powder with B₂O₃ precipitated on the surface thereof and having an average grain size of 1 μm were prepared. The Fe powder, Pt powder and SiO₂ powder were weighed to achieve a target composition of 45 Fe-45 Pt-10 SiO₂ (mol %). And, the B content was 70 wtppm.

Subsequently, the Fe powder, Pt powder and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1100° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 4, Fe powder having an average grain size of 7 μm, Pt powder having average grain size of 2 μm, and amorphous SiO₂ powder having an average grain size of 1 μm were prepared. The Fe powder, Pt powder and SiO₂ powder were weighed to achieve a target composition of 45 Fe-45 Pt-10 SiO₂ (mol %). Here, B was not added.

Subsequently, the Fe powder, Pt powder and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1100° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.89% in Example 8, and a higher density target was obtained compared to the relative density of 95.12% in Comparative Example 4. As a result of sputtering this target, the number of particles generated in a stationary state was 3 in Example 8, and it was confirmed that the number of particles decreased compared to the 31 particles of Comparative Example 4. Thus, when B is added in an amount of 10 wtppm or more, a high density target was obtained and the number of generated particles decreased.

### Example 9, Comparative Example 5

In Example 9, Co powder having an average grain size of 3 μm, Pt powder having an average grain size of 2 μm, and amorphous SiO₂ powder with B₂O₃ precipitated on the surface thereof and having an average grain size of 1 μm were prepared. The Co powder, Pt powder and SiO₂ powder were weighed to achieve a target composition of 78 Co-12 Pt-10 SiO₂ (mol %). And, the B content was 70 wtppm.

Subsequently, the Co powder, Pt powder and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 5, Co powder having an average grain size of 3 μm, Pt powder having average grain size of 2 μm, and amorphous SiO₂ powder having an average grain size of 1 μm were prepared. The Fe powder, Pt powder and SiO₂ powder were weighed to achieve a target composition of 78 Co-12 Pt-10 SiO₂ (mol %). Here, B was not added.

Subsequently, the Co powder, Pt powder and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.67% in Example 9, and a higher density target was obtained compared to the relative density of 95.21% in Comparative Example 5. As a result of sputtering this target, the number of particles generated in a stationary state was 3 in Example 9, and it was confirmed that the number of particles decreased compared to the 32 particles of Comparative Example 5. Thus, when B is added in an amount of 10 wtppm or more, a high density target was obtained and the number of generated particles decreased.

### Example 10, Comparative Example 6

In Example 10, Fe powder having an average grain size of 7 μm, Pt powder having an average grain size of 2 μm, amorphous SiO₂ powder with B₂O₃ precipitated on the surface thereof and having an average grain size of 1 μm, and C powder having an average grain size of 0.05 μm were prepared. The Fe powder, Pt powder, SiO₂ powder, and C powder were weighed to achieve a target composition of 38 Fe-38 Pt-9 SiO₂-15 C (mol %). And, the B content was 300 wtppm.

Subsequently, the Fe powder, Pt powder, SiO₂ powder with B₂O₃ precipitated on the surface thereof, and C powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1100° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 6, Fe powder having an average grain size of 7 μm, Pt powder having average grain size of 2 μm, amorphous SiO₂ powder having an average grain size of 1 μm, and C powder having an average grain size of 0.05 μm were prepared. The Fe powder, Pt powder, SiO₂ powder, and C powder were weighed to achieve a target composition of 38 Fe-38 Pt-9 SiO₂-15 C (mol %). Here, B was not added.

Subsequently, the Fe powder, Pt powder, SiO₂ powder and C powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1100° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.51% in Example 10, and a higher density target was obtained compared to the relative density of 94.30% in Comparative Example 6. As a result of sputtering this target, the number of particles generated in a stationary state was 30 in Example 10, and it was confirmed that the number of particles decreased compared to the 150 particles of Comparative Example 6. Thus, when B is added in an amount of 10 wtppm or more, a high density target was obtained and the number of generated particles decreased.

### Example 11, Comparative Example 7

In Example 11, Co powder having an average grain size of 3 μm, Cr powder having an average grain size of 5 μm, Pt powder having an average grain size of 2 μm, TiO₂ powder having an average grain size of 1 μm, amorphous SiO₂ powder with B₂O₃ precipitated on the surface thereof and having an average grain size of 1 μm, and Cr₂O₃ powder having an average grain size of 0.5 μm were prepared. The Co powder, Cr powder, Pt powder, TiO₂ powder, SiO₂ powder, and Cr₂O₃ powder were weighed to achieve a target composition of 68 Co-10 Cr-12 Pt-2 TiO₂-4 SiO₂-4 Cr₂O₃ (mol %). And, the B content was 300 wtppm.

Subsequently, the Co powder, Cr powder, Pt powder, TiO₂ powder, SiO₂ powder with B₂O₃ precipitated on the surface thereof, and Cr₂O₃ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 950° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 7, Co powder having an average grain size of 3 μm, Cr powder having an average grain size-of 5 μm, Pt powder having an average grain size of 2 μm, TiO₂ powder having an average grain size of 1 μm, amorphous SiO₂ powder having an average grain size of 1 μm, and Cr₂O₃ powder having an average grain size of 0.5 μm were prepared. The Co powder, Cr powder, Pt powder, TiO₂ powder, SiO₂ powder, and Cr₂O₃ powder were weighed to achieve a target composition of 68 Co-10 Cr-12 Pt-2 TiO₂-4 SiO₂-4 Cr₂O₃ (mol %). Here, B was not added.

Subsequently, the Co powder, Cr powder, Pt powder, TiO₂ powder, SiO₂ powder, and Cr₂O₃ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 950° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.65% in Example 11, and a higher density target was obtained compared to the relative density of 96.47% in Comparative Example 7. As a result of sputtering this target, the number of particles generated in a stationary state was 2 in Example 11, and it was confirmed that the number of particles decreased compared to the 13 particles of Comparative Example 7. Thus, when B is added in an amount of 10 wtppm or more, a high density target was obtained and the number of generated particles decreased.

### Example 12, Comparative Example 8

In Example 12, Co powder having an average grain size of 3 μm, Cr powder having an average grain size of 5 μm, Pt powder having an average grain size of 2 μm, amorphous SiO₂ powder with B₂O₃ precipitated on the surface thereof and having an average grain size of 1 μm, and Ta₂O₅ powder having an average grain size of 1 μm were prepared. The Co powder, Cr powder, Pt powder, SiO₂ powder, and Ta₂O₅ powder were weighed to achieve a target composition of 65 Co-10 Cr-15 Pt-5 SiO₂-5 Ta₂O₅ (mol %). And, the B content was 300 wtppm.

Subsequently, the Co powder, Cr powder, Pt powder, SiO₂ powder with B₂O₃ precipitated on the surface thereof, and Ta₂O₅ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1000° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 8, Co powder having an average grain size of 3 μm, Cr powder having an average grain size of 5 μm, Pt powder having an average grain size of 2 μm, amorphous SiO₂ powder having an average grain size of 1 μm, and Ta₂O₅ powder having an average grain size of 1 μm were prepared. The Co powder, Cr powder, Pt powder, SiO₂ powder, and Ta₂O₅ powder were weighed to achieve a target composition of 65 Co-10 Cr-15 Pt-5 SiO₂-5 Ta₂O₅ (mol %). Here, B was not added.

Subsequently, the Co powder, Cr powder, Pt powder, SiO₂ powder, and Ta₂O₅ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1000° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.85% in Example 12, and a higher density target was obtained compared to the relative density of 96.56% in Comparative Example 8. As a result of sputtering this target, the number of particles generated in a stationary state was 3 in Example 12, and it was confirmed that the number of particles decreased compared to the 21 particles of Comparative Example 8. Thus, when B is added in an amount of 10 wtppm or more, a high density target was obtained and the number of generated particles decreased.

### Example 13, Comparative Example 9

In Example 13, Co powder having an average grain size of 3 μm, Cr powder having an average grain size of 5 μm, Pt powder having an average grain size of 2 μm, TiO₂ powder having an average grain size of 1 μm, amorphous SiO₂ powder with B₂O₃ precipitated on the surface thereof and having an average grain size of 1 μm, and CoO powder having an average grain size of 1 μm were prepared. The Co powder, Cr powder, Pt powder, TiO₂ powder, SiO₂ powder, and CoO powder were weighed to achieve a target composition of 71 Co-8 Cr-12 Pt-3 TiO₂-3 SiO₂-3 CoO (mol %). And, the B content was 300 wtppm.

Subsequently, the Co powder, Cr powder, Pt powder, TiO₂ powder, SiO₂ powder with B₂O₃ precipitated on the surface thereof, and CoO powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 900° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 9, Co powder having an average grain size of 3 μm, Cr powder having an average grain size of 5 μm, Pt powder having an average grain size of 2 μm, TiO₂ powder having an average grain size of 1 μm, amorphous SiO₂ powder having an average grain size of 1 μm, and CoO powder having an average grain size of 1 μm were prepared. The Co powder, Cr powder, Pt powder, TiO₂ powder, SiO₂ powder, and CoO powder were weighed to achieve a target composition of 71 Co-8 Cr-12 Pt-3 TiO₂-3 SiO₂-3 CoO (mol %). Here, B was not added.

Subsequently, the Co powder, Cr powder, Pt powder, TiO₂ powder, SiO₂ powder, and CoO powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 900° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.34% in Example 13, and a higher density target was obtained compared to the relative density of 95.56% in Comparative Example 9. As a result of sputtering this target, the number of particles generated in a stationary state was 3 in Example 13, and it was confirmed that the number of particles decreased compared to the 25 particles of Comparative Example 9. Thus, when B is added in an amount of 10 wtppm or more, a high density target was obtained and the number of generated particles decreased.

### Example 14, Comparative Example 10

In Example 14, Co powder having an average grain size of 3 μm, Cr powder having an average grain size of 5 μm, Pt powder having an average grain size of 2 μm, Ru powder having an average grain size of 5 μm, and amorphous SiO₂ powder with B₂O₃ precipitated on the surface thereof and having an average grain size of 1 μm were prepared. The Co powder, Cr powder, Pt powder, Ru powder, and SiO₂ powder were weighed to achieve a target composition of 66 Co-12 Cr-14 Pt-3 Ru-5 SiO₂ (mol %). And, the B content was 300 wtppm.

Subsequently, the Co powder, Cr powder, Pt powder, Ru powder, and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 10, Co powder having an average grain size of 3 μm, Cr powder having an average grain size of 5 μm, Pt powder having an average grain size of 2 μm, Ru powder having an average grain size of 5 μm, and amorphous SiO₂ powder having an average grain size of 1 μm were prepared. The Co powder, Cr powder, Pt powder, Ru powder, and SiO₂ powder were weighed to achieve a target composition of 66 Co-12 Cr-14 Pt-3 Ru-5 SiO₂ (mol %). Here, B was not added.

Subsequently, the Co powder, Cr powder, Pt powder, Ru powder, and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 98.40% in Example 14, and a higher density target was obtained compared to the relative density of 96.25% in Comparative Example 10. As a result of sputtering this target, the number of particles generated in a stationary state was 2 in Example 14, and it was confirmed that the number of particles decreased compared to the 24 particles of Comparative Example 10. Thus, when B is added in an amount of 10 wtppm or more, a high density target was obtained and the number of generated particles decreased.

### Example 15, Comparative Example 11

In Example 15, Co powder having an average grain size of 3 μm, Cr powder having an average grain size of 5 μm, Pt powder having an average grain size of 2 μm, Ti powder having an average grain size of 5 μm, V powder having an average grain size of 70 μm, Co—Mn powder having an average grain size of 50 μm, Zr powder having an average grain size of 30 μm, Nb powder having an average grain size of 20, Mo powder having an average grain size of 1.5 μm, W powder having an average grain size of 4 μm, and amorphous SiO₂ powder with B₂O₃ precipitated on the surface thereof and having an average grain size of 1 μm were prepared. The Co powder, Cr powder, Pt powder, Ti powder, V powder, Co—Mn powder, Zr powder, Nb powder, Mo powder, W powder, and SiO₂ powder were weighed to achieve a target composition of 66 Co-10 Cr-12 Pt-1 Ti-1 V-1 Mn-1 Zr-1 Nb-1 Mo-1 W-5 SiO₂ (mol %). And, the B content was 300 wtppm.

Subsequently, the Co powder, Cr powder, Pt powder, Ti powder, V powder, Co—Mn powder, Zr powder, Nb powder, Mo powder, W powder, and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1000° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 11, Co powder having an average grain size of 3 μm, Cr powder having an average grain size of 5 μm, Pt powder having an average grain size of 2 μm, Ti powder having an average grain size of 5 μm, V powder having an average grain size of 70 μm, Co—Mn powder having an average grain size of 50 μm, Zr powder having an average grain size of 30 μm, Nb powder having an average grain size of 20, Mo powder having an average grain size of 1.5 μm, W powder having an average grain size of 4 μm, and amorphous SiO₂ powder having an average grain size of 1 μm were prepared. The Co powder, Cr powder, Pt powder, Ti powder, V powder, Co—Mn powder, Zr powder, Nb powder, Mo powder, W powder, and SiO₂ powder were weighed to achieve a target composition of 66 Co-10 Cr-12 Pt-1 Ti-1 V-1 Mn-1 Zr-1 Nb-1 Mo-1 W-5 SiO₂ (mol %). Here, B was not added.

Subsequently, the Co powder, Cr powder, Pt powder, Ti powder, V powder, Co—Mn powder, Zr powder, Nb powder, Mo powder, W powder, and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1000° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.46% in Example 15, and a higher density target was obtained compared to the relative density of 95.86% in Comparative Example 11. As a result of sputtering this target, the number of particles generated in a stationary state was 8 in Example 15, and it was confirmed that the number of particles decreased compared to the 25 particles of Comparative Example 11. Thus, when B is added in an amount of 10 wtppm or more, a high density target was obtained and the number of generated particles decreased.

### Example 16, Comparative Example 12

In Example 16, Co powder having an average grain size of 3 μm, Cr powder having an average grain size of 5 μm, Pt powder having an average grain size of 2 μm, SiN powder having an average grain size of 1 μm, SiC powder having an average grain size of 1 μm, and amorphous SiO₂ powder with B₂O₃ precipitated on the surface thereof and having an average grain size of 1 μm were prepared. The Co powder, Cr powder, Pt powder, SiN powder, SiC powder, and SiO₂ powder were weighed to achieve a target composition of 71 Co-10 Cr-12 Pt-1 SiN-1 SiC-5 SiO₂ (mol %). And, the B content was 300 wtppm.

Subsequently, the Co powder, Cr powder, Pt powder, SiN powder, SiC powder, and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 12, Co powder having an average grain size of 3 μm, Cr powder having an average grain size of 5 μm, Pt powder having an average grain size of 2 μm, SiN powder having an average grain size of 1 μm, SiC powder having an average grain size of 1 μm, and amorphous SiO₂ powder having an average grain size of 1 μm were prepared. The Co powder, Cr powder, Pt powder, SiN powder, SiC powder, and SiO₂ powder were weighed to achieve a target composition of 71 Co-10 Cr-12 Pt-1 SiN-1 SiC-5 SiO₂ (mol %). Here, B was not added.

Subsequently, the Co powder, Cr powder, Pt powder, SiN powder, SiC powder, and SiO₂ powder were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 97.57% in Example 16, and a higher density target was obtained compared to the relative density of 96.24% in Comparative Example 12. As a result of sputtering this target, the number of particles generated in a stationary state was 2 in Example 16, and it was confirmed that the number of particles decreased compared to the 19 particles of Comparative Example 12. Thus, when B is added in an amount of 10 wtppm or more, a high density target was obtained and the number of generated particles decreased.

### Example 17, Comparative Example 13

In Example 17, Co powder having an average grain size of 3 μm, Cr powder having an average grain size of 5 μm, Pt powder having an average grain size of 2 μm, Ta powder having an average grain size of 20 μm, and amorphous SiO₂ powder with B₂O₃ precipitated on the surface thereof and having an average grain size of 1 μm were prepared. The Co powder, Cr powder, Pt powder, Ta powder, and SiO₂ powder were weighed to achieve a target composition of 66 Co-12 Cr-14 Pt-3 Ta-5 SiO₂ (mol %). And, the B content was 300 wtppm.

Subsequently, the Co powder, Cr powder, Pt powder, Ta powder, and SiO₂ powder with B₂O₃ precipitated on the surface thereof were placed in a 10-liter ball mill pot together with zirconia balls as the grinding medium, and rotated and mixed for 20 hours.

This mixed powder was filled in a carbon mold and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

In Comparative Example 13, Co powder having an average grain size of 3 μm, Cr powder having an average grain size of 5 μm, Pt powder having an average grain size of 2 μm, Ta powder having an average grain size of 20 μm, and amorphous SiO₂ powder having an average grain size of 1 μm were prepared. The Co powder, Cr powder, Pt powder, Ta powder, and SiO₂ powder were weighed to achieve a target composition of 66 Co-12 Cr-14 Pt-3 Ta-5 SiO₂ (mol %). Here, B was not added.

Subsequently, the Co powder, Cr powder, Pt powder, Ta powder, and SiO₂ powder were placed in a 10-liter ball mill pot together with zirconia balls as the grinding medium, and rotated and mixed for 20 hours.

This mixed powder was filled in a carbon mold, and hot pressed under the following conditions; vacuum atmosphere, temperature of 1040° C., which was set to be 1200° C. or less to avoid the crystallization of the SiO₂ powder, retention time of 3 hours, and pressure of 30 MPa to obtain a sintered compact. This was further processed with a lathe to obtain a disk-shaped target having a diameter of 180 mm and thickness of 7 mm. The relative density was measured and described in Table 1.

As shown in Table 1, the relative density after hot press was 98.15% in Example 17, and a higher density target was obtained compared to the relative density of 96.33% in Comparative Example 13. As a result of sputtering this target, the number of particles generated in a stationary state was 2 in Example 17, and it was confirmed that the number of particles decreased compared to the 23 particles of Comparative Example 13. Thus, when B is added in an amount of 10 wtppm or more, a high density target was obtained and the number of generated particles decreased.

### INDUSTRIAL APPLICABILITY

The sputtering target for a magnetic recording film target of the present invention yields superior effects of being able to inhibit the generation of micro cracks in a target, inhibit the generation of particles during sputtering, and shorten the burn-in time. Since few particles are generated, a significant effect is yielded in that the percent defective of the magnetic recording film is reduced and cost reduction can be realized. Moreover, shortening of the burn-in time contributes significantly to the improvement of production efficiency.

Hence, the present invention is effective as a ferromagnetic material sputtering target for use in forming a magnetic body thin film of a magnetic recording medium, and particularly for forming a hard disk drive recording layer.

1. A sputtering target for a magnetic recording film containing SiO₂, wherein the sputtering target for a magnetic recording film contains B (boron) in an amount of 10 to 1000 wtppm.

2. The sputtering target for a magnetic recording film according to claim 1, wherein the sputtering target for a magnetic recording film is made from Cr in an amount of 20 mol % or less, SiO₂ in an amount of 1 mol % or more and 20 mol % or less, and remainder being Co.

3. The sputtering target for a magnetic recording film according to claim 1, wherein the sputtering target for a magnetic recording film is made from Cr in an amount of 20 mol % or less, Pt in an amount of 1 mol % or more and 30 mol % or less, SiO₂ in an amount of 1 mol % or more and 20 mol % or less, and remainder being Co.

4. The sputtering target for a magnetic recording film according to claim 1, wherein the sputtering target for a magnetic recording film is made from Fe in an amount of 50 mol % or less, Pt in an amount of 50 mol % or less, and remainder being SiO₂.

5. The sputtering target for a magnetic recording film according to claim 4, additionally containing one or more elements selected from the group consisting of Ti, V, Mn, Zr, Nb, Ru, Mo, Ta, and W in an amount of 0.5 mol % or more and 10 mol % or less.

6. The sputtering target for a magnetic recording film according to claim 5, additionally containing one or more components selected from the group consisting of carbon, oxide other than SiO₂, nitride and carbide.

7. The sputtering target for a magnetic recording film according to claim 6, wherein the sputtering target for a magnetic recording film has a relative density of 97% or higher.

8. A method of producing a sputtering target for use in making a magnetic recording film, comprising the steps of: melting Co and B to prepare an ingot, pulverizing the ingot to produce a powder having a maximum particle size of 20 μm or less, mixing the powder with a magnetic metal powder raw material to produce a mixed powder, and sintering the mixed powder at a temperature of 1200° C. or less, wherein the sputtering target produced thereby contains SiO₂ and boron in an amount of 10 to 1000 wtppm.

9. A method of producing the a sputtering target for use in making a magnetic recording film, comprising the steps of: adding SiO₂ powder to an aqueous solution having B₂O₃ dissolved therein, precipitating B₂O₃ on a surface of the SiO₂ powder, mixing powder obtained by said precipitating step with a magnetic metal powder raw material, and sintering powder obtained by said mixing step at a temperature of 1200° C. or less, wherein the sputtering target produced thereby contains SiO₂ and boron in an amount of 10 to 1000 wtppm.

10. A method according to claim 9, wherein the powder obtained by said step of precipitating B₂O₃ on a surface of the SiO₂ powder is calcined at 200° C. to 400° C. before said mixing step.

11. The sputtering target according to claim 4, wherein the sputtering target contains one or more components selected from the group consisting of carbon, oxide other than SiO₂, nitride, and carbide.

12. The sputtering target according to claim 4, wherein the sputtering target has a relative density of 97% or higher.

13. The sputtering target according to claim 3, wherein the sputtering target contains one or more elements selected from the group consisting of Ti, V, Mn, Zr, Nb, Ru, Mo, Ta, and W in an amount of 0.5 mol % or more and 10 mol % or less.

14. The sputtering target according to claim 13, wherein the sputtering target contains one or more components selected from the group consisting of carbon, oxide other than SiO₂, nitride, and carbide.

15. The sputtering target according to claim 3, wherein the sputtering target contains one or ore components selected from the group consisting of carbon, oxide other than SiO₂, nitride, and carbide.

16. The sputtering target according to claim 3, wherein the sputtering target has a relative density of 97% or higher.

17. The sputtering target according to claim 2, wherein the sputtering target contains one or more elements selected from the group consisting of Ti, V, Mn, Zr, Nb, Ru, Mo, Ta, and W in an amount of 0.5 mol % or more and 10 mol % or less.

18. The sputtering target according to claim 17, wherein the sputtering target contains one or more components selected from the group consisting of carbon, oxide other than SiO₂, nitride, and carbide.

19. The sputtering target according to claim 2, wherein the sputtering target contains one or more components selected from the group consisting of carbon, oxide other than SiO₂, nitride, and carbide.

20. The sputtering target according to claim 2, wherein the sputtering target has a relative density of 97% or higher.
